(19) United States
(12) Patent Application Publication
(10) Pub. No.: US 2020/0199744 A1
(43) Pub. Date: Jun. 25, 2020

(54) METHOD FOR PREPARING MULTILAYER STRUCTURE

(71) Applicant: NANYA TECHNOLOGY CORPORATION, New Taipei City (TW)

(72) Inventor: CHUN-CHENG LIAO, NEW TAIPEI CITY (TW)

(21) Appl. No.: 16/368,200

(22) Filed: Mar. 28, 2019

Related U.S. Application Data
(60) Provisional application No. 62/784,612, filed on Dec. 24, 2018.

(51) Int. Cl. C23C 16/40; C23C 16/455; H01L 21/02

(52) U.S. Cl. CPC C23C 16/403; C23C 16/45553; C23C 16/45527; H01L 21/022; H01L 21/0217; H01L 21/0228; H01L 21/02178; H01L 21/02164; H01L 21/02205

(57) ABSTRACT

The present disclosure relates to a method for preparing a multilayer structure. The method includes operations of disposing a substrate in a reactor; injecting an aluminum-containing compound into the reactor, wherein the aluminum-containing compound is adsorbed on the substrate; pumping down to purge excess aluminum-containing compound from the reactor; and injecting an oxygen-containing compound into the reactor, wherein the oxygen-containing compound reacts with the aluminum-containing compound to form an aluminum-containing layer on the substrate.

### PRIORITY CLAIM AND CROSS REFERENCE

This application claims the priority benefit of U.S. provisional application Ser. No. 62/784,612, filed on Dec. 24, 2018. The entirety of the above-mentioned patent application is hereby incorporated by reference herein and made a part of this specification.

### TECHNICAL FIELD

The present disclosure relates to a method for preparing a multilayer structure, and more particularly, to a method for disposing a multilayer dielectric structure on a patterned substrate.

### DISCUSSION OF THE BACKGROUND

Electronic circuits, such as integrated circuits, display circuits, memory circuits, and power circuits, are being made ever smaller to increase portability and computing power. Silicon dioxide layers are used in a variety of applications in the fabrication of the active and passive features of the electronic circuits. In one application, silicon dioxide layers are used in the fabrication of multilayer etch-resistant stacks.

SiO₂ is known in semiconductor and photovoltaic industries to be a passivation material leading to a strong reduction in surface recombination. A high-quality SiO₂ layer is grown by wet thermal oxidation at 900° C. or dry oxidation at between 850° C. and 1000° C. Such high temperatures are generally not compatible with photovoltaic device manufacturing. Therefore, alternative methods were developed such as Chemical Vapor Deposition (CVD) of SiO₂ from TEOS (Tetraethoxysilane) with O₂. However, one of the drawbacks of CVD is the difficulty of controlling the thickness and consequently the resulting inhomogeneity of the film. Another disadvantage is the relatively poor passivation of CVD SiO₂. For these reasons, atomic layer deposition (ALD) is preferred as it produces a homogeneous layer with good passivation properties.

SiO₂ has passivation capabilities but, due to the drawbacks discussed above, Al₂O₃ passivation is now considered. As for SiO₂ layers, recent studies of Al₂O₃ deposition demonstrate that the layer is naturally enriched with hydrogen during deposition. Al₂O₃ contains a reasonable level of hydrogen and therefore it is not strictly necessary to is add H₂ to the N₂.

This Discussion of the Background section is provided for background information only. The statements in this Discussion of the Background are not an admission that the subject matter disclosed in this Discussion of the Background section constitute prior art to the present disclosure, and no part of this Discussion of the Background section may be used as an admission that any part of this application, including this Discussion of the Background section, constitutes prior art to the present disclosure.

### SUMMARY

One aspect of the present disclosure provides a method for preparing a multilayer structure. The method comprises the steps of disposing a substrate in a reactor; injecting an aluminum-containing compound into the reactor, wherein the aluminum-containing compound is adsorbed on the substrate; pumping down to purge excess aluminum-containing compound from the reactor; and injecting an oxygen-containing compound into the reactor, wherein the oxygen-containing compound reacts with the aluminum-containing compound to form an aluminum-containing layer on the substrate.

In some embodiments, the substrate has a patterned layer, and the aluminum-containing compound is adsorbed on the patterned layer.

In some embodiments, the aluminum-containing layer is an aluminum oxide layer selected from the group consisting of Al(Me)₃, Al(Et)₃, Al(Me)₂(OiPr), Al(Me)₂(NMe)₂ and Al(Me)₂(NE)₂.

In some embodiments, the oxygen-containing compound is vapor, O₂, or O₃.

In some embodiments, the method further comprises repeating the following steps for predetermined cycles: injecting the aluminum-containing compound into the reactor, wherein the aluminum-containing compound is adsorbed on the substrate; pumping down to purge excess aluminum-containing compound from the reactor; and injecting the oxygen-containing compound into the reactor, wherein the oxygen-containing compound reacts with the aluminum-containing compound.

In some embodiments, the method further comprises forming a dielectric layer on the aluminum-containing layer.

In some embodiments, the method further comprises injecting the aluminum-containing compound into the reactor, wherein the aluminum-containing compound is adsorbed on the dielectric layer; pumping down to purge excess aluminum-containing compound from the reactor; and injecting the oxygen-containing compound into the reactor, wherein the oxygen-containing compound reacts with the aluminum-containing compound.

In some embodiments, the dielectric layer is a silicon oxide layer, silicon nitride layer, or high-k layer.

In some embodiments, the high-k layer is a hafnium-containing layer or a zirconium-containing layer.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the is concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1 is a cross-sectional view showing a substrate with a resist layer formed thereon.

FIG. 2 is a cross-sectional view showing the substrate in FIG. 1 with the resist layer exposed to a pattern of radiation.

FIG. 3 is a cross-sectional view showing the substrate in FIG. 1 with a patterned resist layer formed thereon.

FIG. 4 is a flowchart showing a method 100 of preparing a multilayer structure, in accordance with an embodiment of the present disclosure.

FIG. 5 is a cross-sectional view showing an operation S11 of the method for preparing a multilayer structure, in accordance with an embodiment of the present disclosure.

FIG. 6 is a cross-sectional view showing an operation S13 of the method for preparing a multilayer structure, in accordance with an embodiment of the present disclosure.

FIG. 7 is a cross-sectional view showing an operation S15 of the method for preparing a multilayer structure, in accordance with an embodiment of the present disclosure.

FIGS. 8 and 9 are cross-sectional views showing an operation S17 of the method for preparing a multilayer structure, in accordance with an embodiment of the present disclosure.

FIG. 10 is a cross-sectional view showing an operation S19 of the method for preparing a multilayer structure, in accordance with an embodiment of the present disclosure.

FIG. 11 is a cross-sectional view showing an operation of the method 100 for preparing a multilayer structure, in accordance with an embodiment of the present disclosure.

FIG. 12 is a cross-sectional view showing an intervening layer between two aluminum-containing layers (Al-containing layers), in accordance with an embodiment of the present disclosure.

FIG. 13 is a cross-sectional view showing an intervening layer between an aluminum-containing layer and a patterned layer, in accordance with an embodiment of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, is are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

Further, spatially relative terms, such as “beneath,” “below,” “lower,” “above,” “upper” and the like, may be used herein for ease of description to describe one element or feature's relationship to another is element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

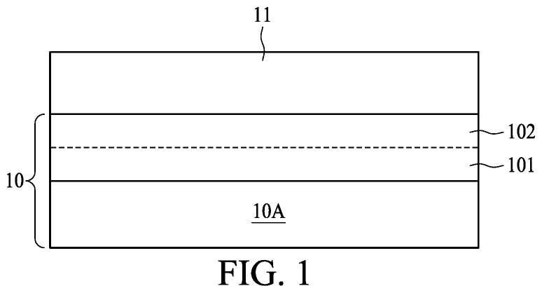

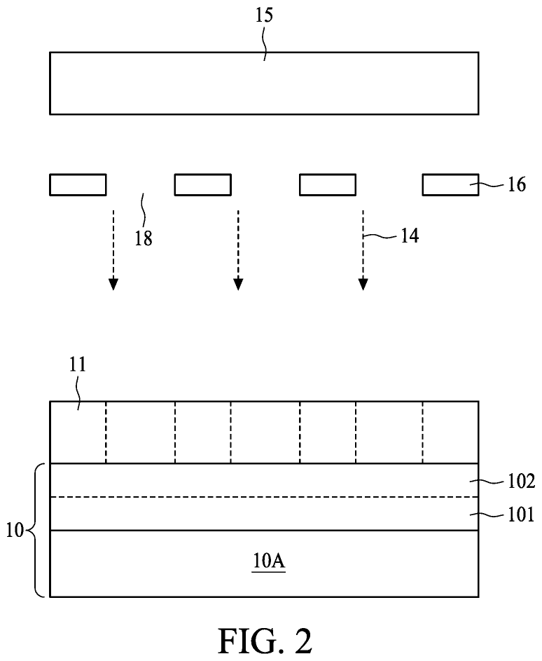

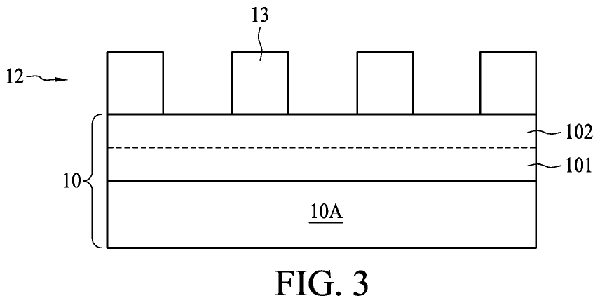

FIG. 1 is a cross-sectional view of a substrate 10 with a resist layer 11 formed thereon. FIG. 2 is a cross-sectional view of the substrate 10 while the resist layer 11 is exposed to a pattern of radiation. FIG. 3 is a cross-sectional view of the substrate 10 with a patterned resist layer 12 having a plurality of resist features 13 that are spaced apart from one another formed on the substrate 10 using a lithography process.

Silicon dioxide layers deposited by the current processes on substrates have different applications. The substrates can be, for example, (i) a semiconducting wafer such as a silicon wafer, germanium wafer, or silicon germanium wafer; (ii) a compound semiconductor wafer such as gallium arsenide; or (iii) a dielectric panel, such as a glass or polymer panel, which can include borophosphosilicate glass, phosphosilicate glass, borosilicate glass, and phosphosilicate glass, polymers and other materials. The substrate 10 can also include one or more layers 101 and 102 on a semiconductor substrate 10A, as shown in FIG. 1. In some embodiments, the layers 101 and 102 may be made from metal-containing, dielectric or semiconducting materials. The layers 101 and 102 can represent a single continuous layer, segmented layer, or different active or passive features, such as integrated circuits, display components, photovoltaic is components, transistors, and the like, which are located in the substrate 10 or on the surface of the substrate 10.

An exemplary embodiment of a process useful for fabricating a multilayer structure on the substrate 10 is illustrated in FIGS. 1 to 11. Referring to FIG. 1, the resist layer 11 is formed on the substrate 10. In some embodiments, the resist layer 11 is formed on the layer 102 of the substrate 10. Typically, the resist layer 11 is spin-coated over the layer 102, which is the uppermost layer of the substrate 10. The resist layer 11 is patterned to form the patterned resist layer 12 having resist features 13 which serve as etch-resistant features to transfer a pattern to the underlying layer 102 of the substrate 10 by etching through the exposed portions of the layer 102 that lie between the resist features 13.

In some embodiments, the resist layer 11 is a photoresist layer, which is a radiation-sensitive material that is not limited to photon or light-sensitive materials, and can be a light-sensitive, electron-sensitive, X-ray sensitive or other radiation-sensitive material. In some embodiments, the photoresist layer is a positive photoresist or negative photoresist that is sensitive to light. A positive photoresist is one in which the portion of the photoresist that is exposed to light becomes soluble to a photoresist developer, and the portion that is unexposed remains insoluble to a photoresist developer. A negative resist is one in which the portion of the photoresist that is exposed to light becomes insoluble to the photoresist developer, and the unexposed portion is dissolved by the photoresist developer. The photoresist layer may include photoresist material, such as Polymethylmethacrylate (PMMA), PolyMethylGlutarimide (PMGI), Phenol formaldehyde resin, a combination of diazonaphthoquinone (DNQ) and novolac resin (a phenol formaldehyde resin), or SU-8, is which is an epoxy-based negative photoresist. The available resist layers 11 include Hoechst AZ 4620, Hoechst AZ 4562, Shipley 1400-17, Shipley 1400-27, Shipley 1400-37, and Shipley Microposit Developer. In some embodiments, the photoresist layer is formed to a thickness between about 20 nm and about 500 nm, for example, from about 50 nm to about 200 nm, or even about 120 to 150 nm.

The resist layer 11 can be applied as a liquid by dip coating or spin-coating. In the spin-coating process, the liquid resist is dispensed over the surface of the substrate 10, while the substrate 10 is rapidly spun until it becomes dry. Spin-coating processes are often conducted at spinning speeds of from about 3000 rpm to about 7000 rpm for about 20 to about 30 seconds. The resist layer application is followed by a soft bake process that heats the spin-coated resist layer to evaporate the solvent from the spun-on resist, improve the adhesion of the resist to the substrate 10, or anneal the resist layer 11 to reduce shear stresses which are introduced during spin-coating. Soft baking can be performed in an oven, such as a convection, infrared, or hot plate oven. The typical temperature range for soft baking is from about 80° C. to about 100° C. As another example, dry films can also be applied, such as polymer films, which are radiation-sensitive. Dry films may or may not need to be baked or cured depending on the nature of the film.

Thereafter, the resist layer 11, comprising, for example, the photoresist layer, is exposed to a pattern of radiation 14 provided by a radiation source 15 through a mask 16 as shown, for example, in FIG. 2.

The mask 16 can be a plate with holes 18 (as shown) or transparent portions (not shown) that correspond to a pattern which allows radiation 14 to selectively permeate through portions of the mask to form a radiation pattern of intersecting lines or arcs. The masks 16 are is fabricated by conventional methods.

In some embodiments, the photoresist layer is a light-sensitive material such as diazonaphthoquinone. The radiation source 15 provides ultraviolet light having wavelengths of less than 300 nm, for example, about 248 nm, such as a mercury lamp. The photoresist layer comprising diazonaphthoquinone (DNQ) absorbs light having wavelengths from about 300 nm to about 450 nm.

In some embodiments, the photoresist layer is a positive photoresist based on a mixture of diazonaphthoquinone (DNQ) and novolac resin (a phenol formaldehyde resin). A suitable radiation source 15 for this photoresist is a mercury-vapor lamp, set to provide light comprising I, G and H-lines from the mercury-vapor lamp.

In some embodiments, the photoresist layer comprises SU-8, which is a viscous polymer that can be spun or spread over a thickness ranging from 0.1 micrometer to 2 millimeters and processed with standard contact lithography. Advantageously, this photoresist layer can be used to pattern resist features 13 which have a high aspect ratio (ratio of a feature's height to its width) that is equal to or greater than 20. In this embodiment, the radiation source 15 provides ultraviolet light having a wavelength of 193 nm.

In some embodiments, the photoresist layer comprises an electron-sensitive material, and the radiation source 15 is an electron beam source. Electron beam lithography usually relies on photoresist materials that are produced specifically for electron-beam exposure. Conventional electron beam lithography techniques and materials can be used.

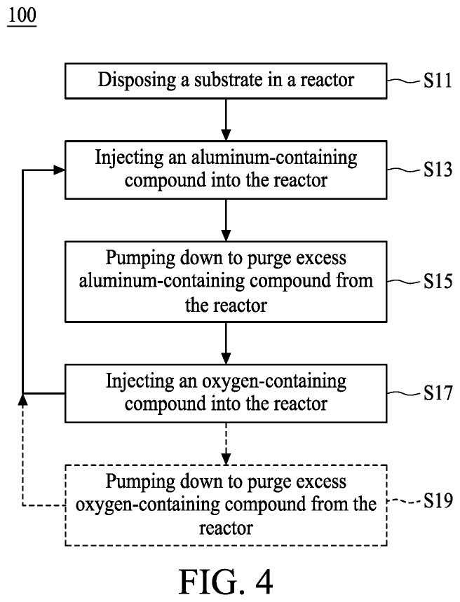

FIG. 4 is a flowchart showing a method 100 of preparing a is multilayer structure, in accordance with an embodiment of the present disclosure. In some embodiments, the method 100 includes a number of operations (S11, S13, S15, S17 and S19), and the description and illustrations are not deemed as a limitation as the sequence of the operations.

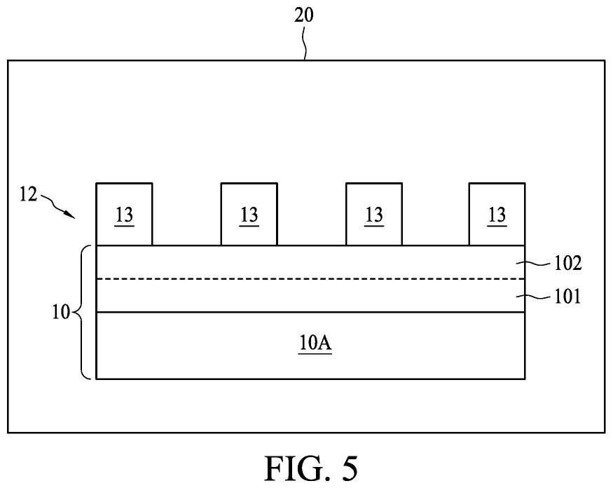

FIG. 5 is a cross-sectional view showing the operation S11 of the method 100 for preparing a multilayer structure, in accordance with an embodiment of the present disclosure. In operation S11, the substrate 10 is disposed in a reactor 20. In some embodiments, the substrate 10 includes a carbon hard mask and a silicon-oxy nitride layer below a patterned layer 12. In some embodiments, the patterned layer 12 is a resist layer having resist features 13. In some embodiments, the resist layer is a photoresist layer. In some embodiments, the photoresist layer is a radiation-sensitive material or a light-sensitive material. In some embodiments, the substrate includes one or more layers (for example, layers 101 and 102 in FIG. 1).

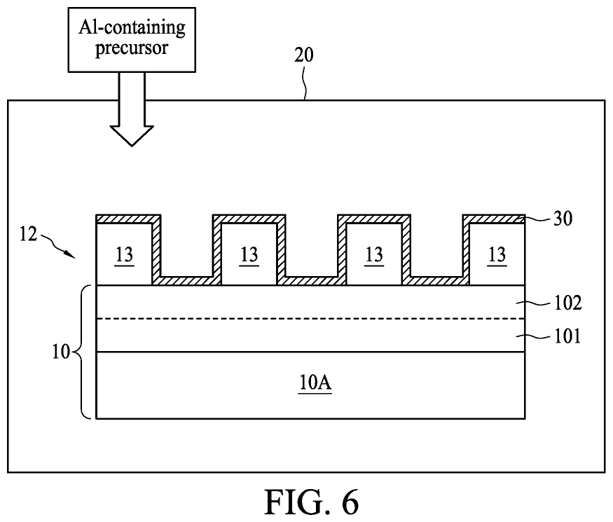

FIG. 6 is a cross-sectional view showing the operation S13 of the method 100 for preparing a multilayer structure, in accordance with an embodiment of the present disclosure. In operation S13, an aluminum-containing compound (Al-containing compound) 30 is injected into the reactor 20 and the aluminum-containing compound 30 is adsorbed on the patterned layer 12.

In some embodiments, the vaporization of the aluminum-containing precursor can be performed by introducing a canister containing the aluminum-containing compound 30 according to the present disclosure. In some embodiments, the aluminum-containing compound 30 is selected from the group is consisting of Al(Me)₃, Al(Et)₃, Al(Me)₂(OiPr), Al(Me)₂(NMe)₂ and

Al(Me)₂(NEt)₂.

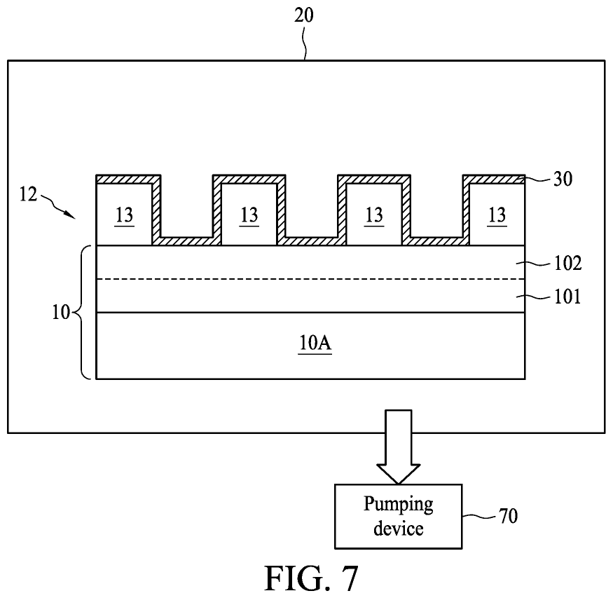

FIG. 7 is a cross-sectional view showing the operation S15 of the method 100 for preparing a multilayer structure, in accordance with an embodiment of the present disclosure. In operation S15, the reactor 20 is pumped down and the excess aluminum-containing compound 30 is purged from the reactor 20.

In some embodiments, the reactor 20 is pumped down by a pumping device 70 and the excess aluminum-containing compound 30 is purged from the reactor 20. That is, the excess aluminum-containing compound 30, which is not adsorbed on the substrate 10 (or the patterned layer 12), may be purged while the reactor 20 is pumped down.

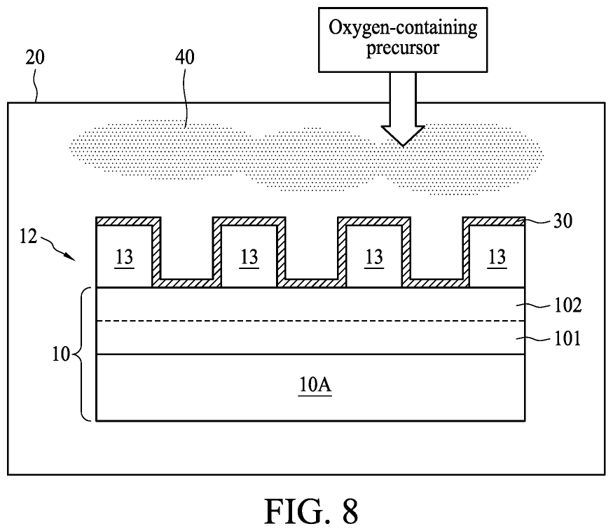

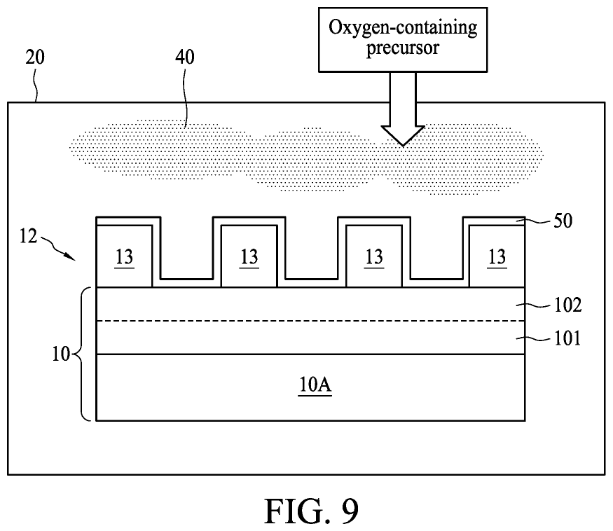

FIGS. 8 and 9 are cross-sectional views showing the operation S17 of the method 100 for preparing a multilayer structure, in accordance with an embodiment of the present disclosure. In operation S17, an oxygen-containing compound 40 is injected into the reactor 20 and the oxygen-containing compound 40 reacts with the aluminum-containing compound 30 to form an aluminum-containing layer 50 on the substrate.

In some embodiments, the vaporization of the oxygen-containing precursor can be performed by introducing a canister containing the oxygen-containing compound 40 according to the present disclosure. In some embodiments, the aluminum-containing layer 50 is formed on the patterned layer 12. In some embodiments, the aluminum-containing layer 50 is an Al₂O₃ layer. In some embodiments, the oxygen-containing compound 40 is is vapor, O₂, or O₃.

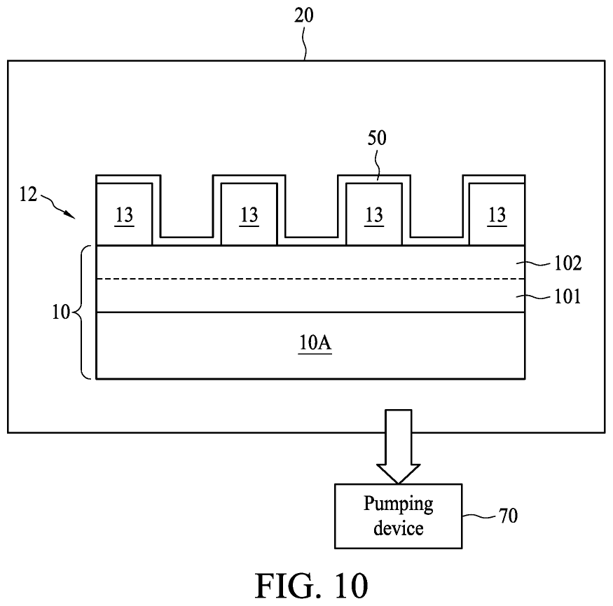

FIG. 10 is a cross-sectional view showing the operation S19 of the method 100 for preparing a multilayer structure, in accordance with an embodiment of the present disclosure. In operation S19, the reactor 20 is pumped down and the excess oxygen-containing compound 40 is purged from the reactor 20. In some embodiments, the reactor 20 is pumped down by a pumping device 70 and the excess oxygen-containing compound 40 is purged from the reactor 20. That is, the excess oxygen-containing compound 40, which has not reacted with the aluminum-containing compound 30, may be purged while the reactor 20 is pumped down.

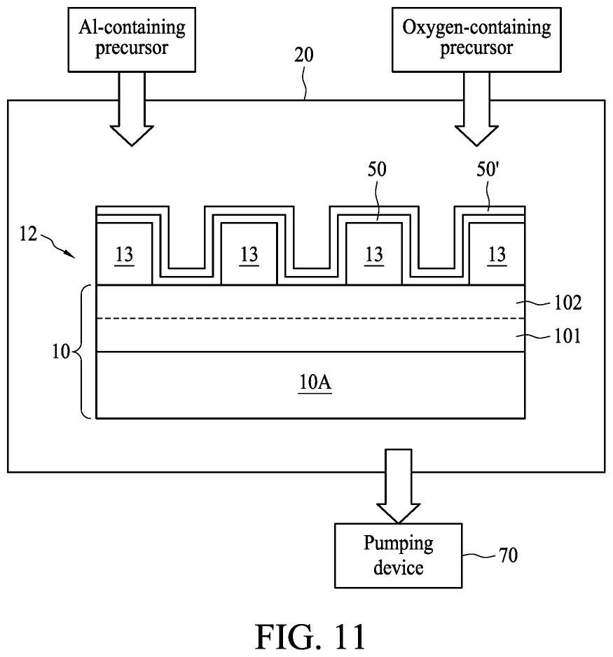

FIG. 11 is a cross-sectional view showing the method 100 for preparing a multilayer structure, in accordance with an embodiment of the present disclosure. In some embodiments, the operations S13 to S17 are repeated one additional cycle to form the multilayer dielectric structure with desired thickness.

In some embodiments, the operations S13 to S17 are repeated for a predetermined number of cycles to obtain a desired thickness of the multilayer aluminum-containing layers or a multilayer dielectric structure. In addition, after the first iteration of operation S17 and before repeating the operations S13 to S17, the operation S19 may be included to pump down for purging the excess oxygen-containing compound 40 from the reactor 20.

In FIG. 11, for example, there are two aluminum-containing layers 50, 50′ formed on the patterned layer 12. That is, after a first cycle of the operations S13 to S17 are performed to form the aluminum-containing layer (the first Al-containing layer) 50, a second cycle of the operations S13 to S17 are performed to form the aluminum-containing layer (the second Al-containing layer) 50′ on the aluminum-containing layer 50. The multilayer structure of the present disclosure may be implemented by repeating the operations S13 to S17 for a predetermined number cycles to form the multilayer structure with desired thickness. That is, the thickness of the multilayer structure is controllable.

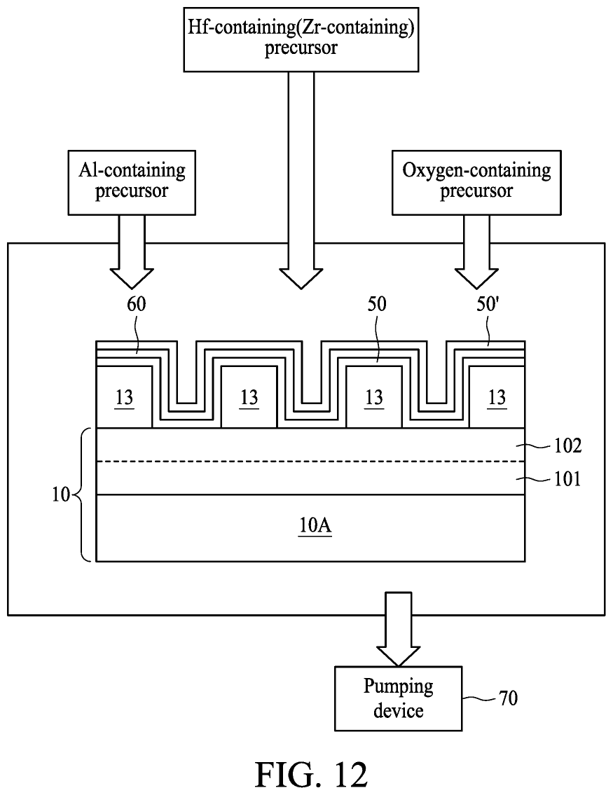

FIG. 12 is a cross-sectional view showing an intervening layer 60 between two aluminum-containing layers, in accordance with an embodiment of the present disclosure. In some embodiments, the intervening layer 60 is a dielectric layer optionally formed between the two aluminum-containing layers 50, 50′. In some embodiments, the intervening layer 60 is a silicon oxide layer, silicon nitride layer, or high-k layer. In some embodiments, the high-k layer is a hafnium-containing layer (Hf-containing layer) or a zirconium-containing layer (Zr-containing layer).

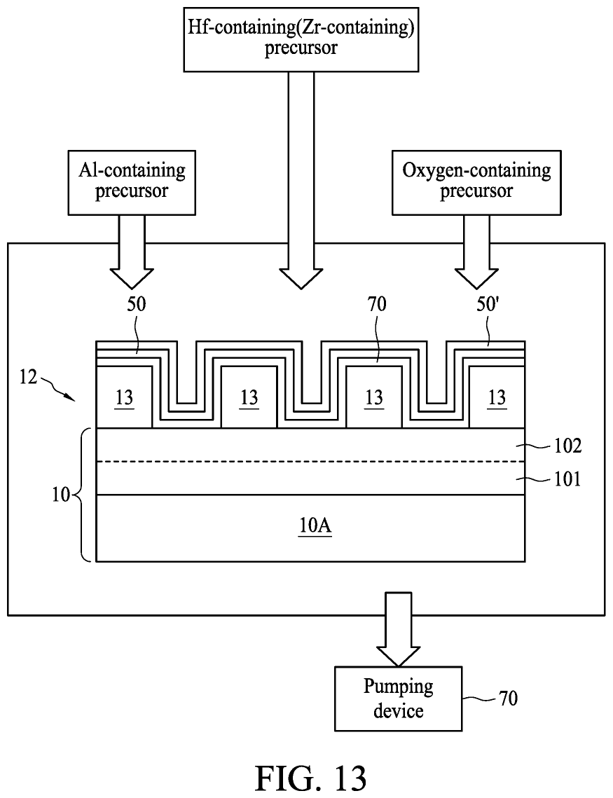

FIG. 13 is a cross-sectional view showing an intervening layer 70 between an aluminum-containing layer and the patterned layer, in accordance with an embodiment of the present disclosure. In some embodiments, the intervening layer 70 is a dielectric layer optionally formed between the aluminum-containing layer 50 and the patterned layer 12. In some embodiments, the intervening layer 70 is a silicon oxide layer, silicon nitride layer, or high-k layer. In some embodiments, the high-k layer is a hafnium-containing layer or a zirconium-containing layer.

In summary, the process of pumping down not only purges the excess aluminum-containing compound (precursor), but also improves the adsorption of the compounds (precursors) on the reaction surface (the surface of the substrate or the surface of the patterned layer).

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods and steps.

What is claimed is:

1. A method for preparing a multilayer structure, comprising:
disposing a substrate in a reactor;
injecting an aluminum-containing compound into the reactor, wherein the aluminum-containing compound is adsorbed on the substrate;
pumping down to purge excess aluminum-containing compound from the reactor; and
injecting an oxygen-containing compound into the reactor, wherein the oxygen-containing compound reacts with the aluminum-containing compound to form an aluminum-containing layer on the substrate.

2. The method of claim 1, wherein the substrate has a patterned layer, and the aluminum-containing compound is adsorbed is on the patterned layer.

3. The method of claim 1, wherein the aluminum-containing layer is an aluminum oxide layer.

4. The method of claim 1, wherein the aluminum-containing compound is selected from the group consisting of Al(Me)₃, Al(Et)₃, Al(Me)₂(OiPr), Al(Me)₂(NMe)₂ and Al(Me)₂(NEt)₂.

5. The method of claim 1, wherein the oxygen-containing compound is vapor, O₂, or O₃.

6. The method of claim 1, further comprising: repeating the following steps for a predetermined number of cycles:
injecting the aluminum-containing compound into the reactor, wherein the aluminum-containing compound is adsorbed on the substrate;
pumping down to purge excess aluminum-containing compound from the reactor; and
injecting the oxygen-containing compound into the reactor, wherein the oxygen-containing compound reacts with the aluminum-containing compound.

7. The method of claim 1, further comprising: forming a dielectric layer on the aluminum-containing layer.

8. The method of claim 7, further comprising:
injecting the aluminum-containing compound into the reactor, wherein the aluminum-containing compound is adsorbed on the dielectric layer;
pumping down to purge excess aluminum-containing compound is from the reactor; and
injecting the oxygen-containing compound into the reactor, wherein the oxygen-containing compound reacts with the aluminum-containing compound.

9. The method of claim 7, wherein the dielectric layer is a silicon oxide layer, silicon nitride layer, or high-k layer.

10. The method of claim 9, wherein the high-k layer is a hafnium-containing layer or a zirconium-containing layer.
